(19) United States
(12) Patent Application Publication
(10) Pub. No.: US 2009/0213675 A1
(43) Pub. Date: Aug. 27, 2009

(54) SEMICONDUCTOR MEMORY DEVICE

(75) Inventor: Tomoaki SHINO, Kawasaki-Shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 12/394,532

(22) Filed: Feb. 27, 2009

(30) Foreign Application Priority Data
Feb. 27, 2008 (JP) 2008-045782

(51) Int. Cl. G11C 7/06; G11C 8/08; G11C 7/00

(52) U.S. Cl. 365/205; 365/230.06; 365/222

(57) ABSTRACT

A memory includes memory cells, wherein in a first cycle of writing first logic data, sense amplifiers apply a first potential to bit lines, drivers apply a second potential to a selected word line and a third potential to a selected source line, and the second and third potentials with reference to the first potential have the same polarities as polarities of the carriers, and in a second cycle of writing second logic data, the sense amplifiers apply a fourth potential to a selected bit line, the drivers apply a fifth potential to the selected word line and a sixth potential to the selected source line and, the sixth potential is nearer to the first potential than the second and third potentials, the fifth potential with reference to the sixth potential has the same polarity as polarities of the carriers, and the fourth potential with reference to the sixth potential has a polarity opposite to the polarities of the carriers.

### CROSS-REFERENCE TO RELATED APPLICATION

This application is based upon and claims the benefit of priority from the prior Japanese Patent Applications No. 2008-45782, filed on Feb. 27, 2008, the entire contents of which are incorporated herein by reference.

### BACKGROUND OF THE INVENTION

1. Field of the Invention

The present invention relates to a semiconductor memory device, and, for example, relates to an FBC (Floating Body Cell) memory storing information by accumulating majority carriers in floating bodies of field-effect transistors.

2. Related Art

In recent years, there are FBC memory devices as semiconductor memory devices expected as memories alternative to 1T (Transistor)-1C (Capacitor) DRAMs. The FBC memory device stores data “1” or data “0” depending on a size of the number of majority carriers accumulated in floating bodies of FETs. In an FBC including n-type FETs, for example, a state of a large number of holes accumulated in a body is called data “1”, and a state of a small number of holes accumulated in a body is called data “0”. A memory cell storing the data “0” is called a “0” cell, and a memory cell storing the data “1” is called a “1” cell.

At a data writing time, data in a non-selected memory cell connected to a selected bit line is often degraded. This is called a bit-line disturb. At the time of writing data “1”, for example, data in a non-selected “0” cell connected to a selected bit line is degraded (bit line “1” disturb). At the time of writing data “0”, for example, data in a non-selected “1” cell connected to a selected bit line is degraded (bit line “0” disturb).

Generally, to secure a sufficiently large signal difference between data “1” and data “0”, it is necessary to set a large amplitude of a bit line potential (a difference between a bit line potential at the time of writing data “1” and a bit line potential at the time of writing data “0”) at the data writing time.

However, having a large amplitude of a bit line potential becomes a cause of incurring the bit line disturb. Therefore, when a large amplitude of a bit line potential is taken, a refresh operation of recovering from degraded logic data of a memory cell needs to be performed frequently. That is, a refresh busy rate increases. An increase of a refresh busy rate becomes a cause of interrupting normal read/write operations, and becomes a cause of increasing power consumption.

### SUMMARY OF THE INVENTION

A semiconductor memory device according to an embodiment of the present invention comprises: a plurality of memory cells each including a source, a drain, and a floating body in an electrically floating state, the memory cells storing logic data based on number of carriers within the floating body; a plurality of bit lines connected to the drains; a plurality of word lines crossing the bit lines, the word lines functioning as gates of the memory cells or being connected to gates of the memory cells; a plurality of source lines connected to the sources, and extended along the word lines; sense amplifiers detecting data stored in the memory cells; and drivers driving the word lines or the source lines, wherein

in a first cycle of writing first logic data showing a state of a large number of the carriers to the memory cells, the sense amplifiers apply a first potential to the bit lines, the drivers respectively apply a second potential to a selected word line out of the word lines and a third potential to a selected source line out of the source lines, and the second and the third potentials with reference to the first potential have the same polarities as polarities of the carriers, and

in a second cycle of writing second logic data showing a state of a small number of the carriers to the memory cells, the sense amplifiers apply a fourth potential to a selected bit line out of the bit lines, the drivers respectively apply a fifth potential to the selected word line and a sixth potential to the selected source line and, the sixth potential is nearer to the first potential than the second and third potentials, the fifth potential with reference to the sixth potential has the same polarity as the polarities of the carriers, and the fourth potential with reference to the sixth potential has a polarity opposite to the polarities of the carriers.

A semiconductor memory device according to an embodiment of the present invention comprises: a plurality of memory cells each including a source, a drain, and a floating body in an electrically floating state, the memory cells storing logic data based on number of carriers within the floating body; a plurality of bit lines connected to the drains; a plurality of word lines crossing the bit lines, the word lines functioning as gates of the memory cells or being connected to gates of the memory cells; a plurality of source lines connected to the sources, and extended along the word lines; sense amplifiers detecting data stored in the memory cells; and drivers driving the word lines or the source lines, wherein

in the first cycle of driving the selected word line out of the word lines and the selected source line out of the source lines, the drivers write the first logic data showing the state of a large number of the carriers to the memory cells connected to the selected word line and the selected source line, and

in the second cycle of driving the selected bit line out of the plurality of bit lines, the sense amplifiers write the second logic data showing the state of a small number of the carriers selectively to the memory cells connected to the selected bit line out of the memory cells into which the first logic data is written in the first cycle.

A semiconductor memory device according to an embodiment of the present invention comprises: a plurality of memory cells each including a source, a drain, and a floating body in an electrically floating state, the memory cells storing logic data based on number of carriers within the floating body; a plurality of bit lines connected to the drains; a plurality of word lines crossing the bit lines, the word lines functioning as gates of the memory cells or being connected to gates of the memory cells; a plurality of source lines connected to the sources, and extended along the word lines; sense amplifiers detecting data stored in the memory cells; drivers driving the word lines or the source lines; a counter cell array including a plurality of counter cells provided corresponding to the word lines, the counter cell array storing number of activation of the word lines; and an adder circuit incrementing the number of activation of the selected word line, at each time of reading or writing data from or to the memory cells, wherein

adjacent a first and a second word lines out of the word lines are provided corresponding to one of the sources or one of the drains, and

when the number of activation of the first word line becomes a predetermined value, the adder circuit outputs an instruction to perform a refresh operation of the memory cells connected to the second word line, the refresh operation recovering logic data stored in the memory cells.

### BRIEF DESCRIPTION OF THE DRAWINGS

FIG. 1 shows one example of a configuration of an FBC memory according to a first embodiment of the present invention;

FIG. 2 is a plan view showing a part of the memory cell arrays MCA;

FIG. 3A is a cross-sectional view along a line A-A in FIG. 2;

FIG. 3B is a cross-sectional view along a line B-B in FIG. 2;

FIG. 3C is a cross-sectional view along a line C-C in FIG. 2;

FIG. 4A and FIG. 4B are explanatory diagrams showing a data write operation according to the first embodiment;

FIG. 4C shows a potential of each wiring in a data holding state;

FIG. 5 is a timing diagram of voltages applied to the memory cells MC in the first cycle and the second cycle;

FIGS. 6 to 11 are cross-sectional views showing a method of manufacturing the FBC memory according to the first embodiment;

FIG. 12 shows a voltage state in a data holding according to a second embodiment;

FIG. 13 is a timing diagram showing the operation of an FBC memory according to the second embodiment;

FIG. 14 and FIG. 15 are a plan view and a cross-sectional view, respectively of an FBC memory according to a third embodiment of the present invention;

FIG. 16A and FIG. 16B are explanatory diagrams showing a data write operation;

FIG. 17 is a configuration diagram showing one example of the FBC memory according to the third embodiment; and

FIG. 18 to FIG. 20 are cross-sectional views showing one example of an FBC memory constituted by a vertical transistor according to a fourth embodiment of the present invention.

### DETAILED DESCRIPTION OF THE INVENTION

Embodiments of the present invention will be explained below in detail with reference to the accompanying drawings. Note that the invention is not limited thereto.

### First Embodiment

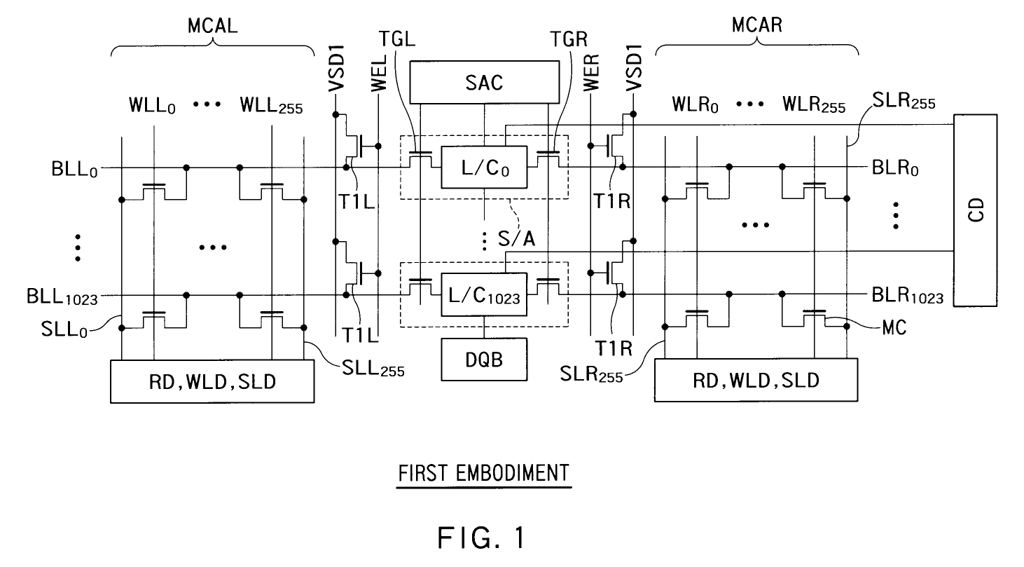

FIG. 1 shows one example of a configuration of an FBC memory according to a first embodiment of the present invention. The FBC memory includes: memory cells MC; word lines WLL0 to WLL255, WLR0 to WLR255 (hereinafter, also “word lines WL”); bit lines BLL0 to BLL1023, BLR0 to BLR1023 (hereinafter, also “bit lines BL”); sense amplifiers S/A; source lines SLL0 to SLL1023, SLR0 to SLL1023 (hereinafter, also “source lines SL”); row decoders RD; word line drivers WLD; source line drivers SLD; a column decoder CD; a sense amplifier controller SAC; and a DQ buffer DQB.

The memory cells MC are arranged two dimensionally in a matrix shape, thereby constituting memory cell arrays MCAL and MCAR (hereinafter, also MCA). The word lines WL are extended to a row direction, and are connected to gates of the memory cells MC. The word lines WL are provided by 256 at each of the left and right sides of the sense amplifiers S/A. The bit lines BL are extended to a column direction, and are connected to drains of the memory cells MC. The bit lines BL are provided by 1,024 at each of the left and right sides of the sense amplifiers S/A. The word lines WL and the bit lines BL are orthogonal with each other, and the memory cells MC are provided at these intersections. Those memory cells are called crosspoint cells. A row direction and a column direction are convenient names, and these can be called by mutually replacing the names. Source lines SL are extended in parallel with the word lines WL, and are connected to sources of the memory cells MC.

At a data reading time, one of the bit lines BLL and BLR connected to the left and right sides of the same sense amplifier S/A transmits a data state, and the other bit line transmits a reference signal. The reference signal is an intermediate current or an intermediate potential between data “1” and data “0”, and is generated by averaging signals of plural dummy cells DC. Accordingly, each sense amplifier S/A reads data from a selected memory cell connected to a selected bit line and a selected word line, or writes data into this selected memory. The sense amplifiers S/A include latch circuits L/CO to L/C1023 (hereinafter, also “latch circuits L/C”), and can temporarily hold data readout from the memory cells MC.

Further, the FBC memory includes N-type transistors T1L and T1R connected between a bit line potential VSD1 and each bit line BL in the write operation of writing data “1”. The transistors T1L and T1R are provided corresponding to each bit line BL. Gates of the transistors T1L and T1R are connected to write-permission or write-enable signals WEL and WER, respectively. The write-permission signals WEL and WER are activated at the time of writing data “1”.

The write operation according to the first embodiment is briefly explained. First, the latch circuits L/C of the sense amplifiers S/A latch data of the memory cells MC in the all columns connected to a selected word line. When the word line WLL1 is a selected word line, the latch circuit L/C latches the data of the all memory cells MC connected to the selected word line WLL1. In this case, the sense amplifier S/A receives a reference signal from the memory cell array MCAR. Next, transfer gates TGL and TGR are set to off, thereby separating the latch circuit L/C from the bit line BL. The transistor T1L is set to on, thereby connecting the potential VSD1 as a first potential to the all bit lines BLL within the memory cell array MCAL. Predetermined potentials are applied to the selected word line WLL1 and the selected source line SL1, respectively. Consequently, data “1” is written into the memory cells of the all columns connected to the selected word line WLL1 (a first cycle). Further, the sense amplifier S/A writes back the data “0” written in the latch circuit L/C to the memory cells MC (the “0” cells) (a second cycle).

In the write operation of writing data from the outside of the memory, the data received from the outside is once stored into the latch circuit L/C via a DQ buffer DQB. In this case, a certain level of time is necessary to store data from the DQ buffer DQB into the latch circuit L/C. When the first cycle is performed using this time, the write operation according to the first embodiment can be performed at two steps, without increasing the total cycle time.

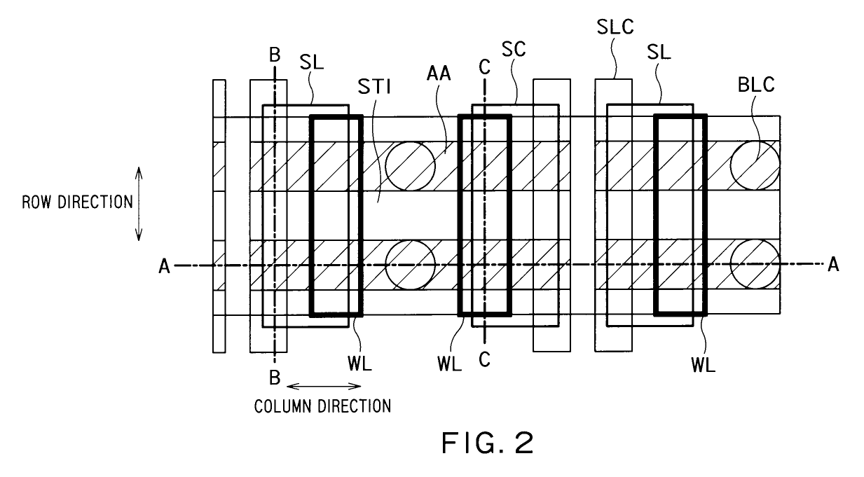

FIG. 2 is a plan view showing a part of the memory cell arrays MCA. Plural active regions AA are extended to a column direction in a stripe shape. A shallow trench isolation STI is formed between adjacent active regions AA. The memory cells MC are formed in the active regions AA.

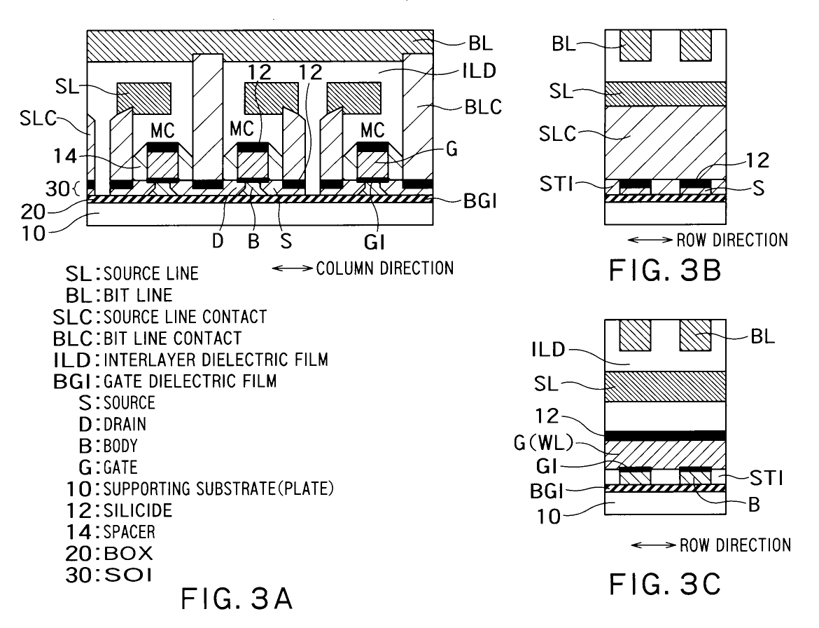

FIG. 3A is a cross-sectional view along a line A-A in FIG. 2. FIG. 3B is a cross-sectional view along a line B-B in FIG. 2. FIG. 3C is a cross-sectional view along a line C-C in FIG. 2. The memory cells MC are formed on an SOI structure including a supporting substrate 10, a BOX (Buried Oxide) layer 20 provided on the supporting substrate 10, and an SOI layer 30 provided on the BOX layer 20.

The BOX layer 20 functions as a back gate dielectric film BGI shown in FIG. 3A. An N-type source S and an N-type drain D are formed in the SOI layer 30 as a semiconductor layer. A P-type floating body B (hereinafter, simply “body B”) in an electrically floating state is provided in the SOI layer 30 between the source S and the drain D. The body B accumulates charges to store logic data, or discharges (extinguishes) charges. The logic data can be binary data of “0” or “1”, or can be multi-value data. The FBC memory according to the first embodiment stores binary data. When the memory cells MC include N-type FETs, memory cells accumulating a large number of holes in the body are set as “1” cells, and the memory cells MC discharging holes from the body are set as “0” cells.

A gate dielectric film GI is provided on each body B, and a gate electrode G is provided on each gate dielectric film GI. A silicide 12 is formed on the gate electrode G, the source S, and the drain D. Accordingly, gate resistance and contact resistance are decreased.

Each source S is connected to the source line SL via a source line contact SLC. The source line contact SLC is provided for each memory cell. That is, the source lines SL are provided corresponding to memory cells arranged in a column direction.

On the other hand, each drain D is connected to the bit line BL via a bit line contact BLC. The drain D is shared by plural memory cells MC adjacent in a column direction. Similarly, the bit line contact BLC is shared by plural memory cells MC adjacent in a column direction.

The gate electrodes G are extended to a row direction, and also function as the word lines WL. The word lines WL can be formed in a layer different from a layer of the gate electrodes G. In this case, a word line contact (not shown) connecting between the word line WL and the gate electrode G is necessary.

A sidewall 14 is formed on a side surface of each gate electrode G. An interlayer dielectric film ILD is filled into between wirings of the source line SL and the bit line BL. FIG. 3A is a cross-sectional view along the bit line BL. The gate electrodes G (the word lines WL) and the source lines SL are extended to a row direction (a direction facing the paper surface in FIG. 3A), and are orthogonal with the bit lines BL.

It is understood from FIG. 3B that the source line SL connected to the sources S via the source line contact SLC are extended to a row direction along the word line WL. It is understood from FIG. 3C that the gate electrode G is extended to a row direction, and also functions as the word line WL.

It is understood from FIG. 3A that a bottom surface of the SOI layer 30 faces a plate via the back gate dielectric film BGI. The plate is a well formed on the supporting substrate 10. Hereinafter, the plate is expressed as (10). The body B can be fully depleted when the plate (10) and the gate electrode G give an electric field to the body B. This FBC is called a fully depleted FBC (FD-FBC). In the FD-FBC, a positive voltage is applied to the gate electrode G at a data reading time, and a channel (an inverted layer) is formed on a surface of the body B, thereby completely depleting the body B. In this case, a negative voltage is applied to the plate (10) to hold holes at a bottom surface side of the body B.

The FBC according to the first embodiment can be a partially depleted FBC (PD-FBC). In the PD-FBC, when a channel is formed by applying a positive voltage to the gate electrode G at a data reading time, the body B is partially depleted. In this case, a neutral region capable of accumulating holes remains in the body B. In the PD-FBC, because holes are held in the neutral region, a negative voltage applied to the plate (10) can be small.

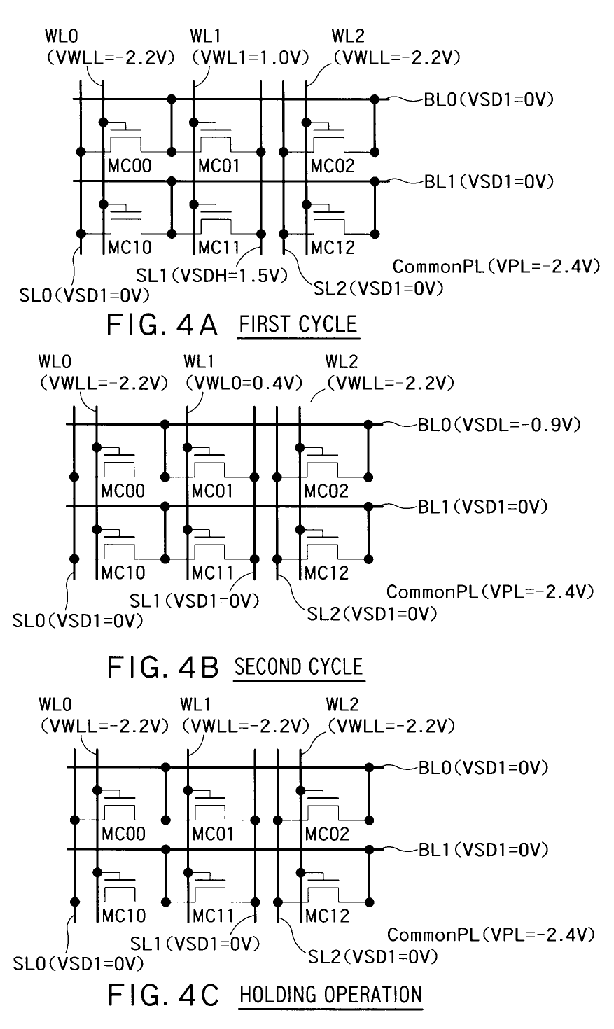

FIG. 4A and FIG. 4B are explanatory diagrams showing a data write operation according to the first embodiment. The data write operation includes two steps of a first cycle and a second cycle.

In the first cycle shown in FIG. 4A, data “1” is written into the all memory cells MC01 and MC11 connected to the selected word line WL1. In this case, a selected word line potential VWL1 as a second potential is biased to the same polarity as polarities of majority carriers of the memory cells MC with reference to the bit line potential VSD1 as a first potential. Further, a selected source line potential VSDH as a third potential is biased to the same polarity as the polarities of the majority carriers with reference to the bit line potential. Polarities of holes are plus (+), and polarities of electrons are minus (−). The majority carriers of the memory cells MC according to the first embodiment are holes.

More specifically, the first potential VSD1 (0 V, for example) is applied to the bit lines BL0 BL1 of the all columns. A second potential VWL1 (1.0 V, for example) higher than the first potential VSDL is applied to the selected word line WL1. A third potential VSDH (1.5 V, for example) higher than the first potential VSD1 is applied to the selected source line SL1. Accordingly, an impact ionization current is generated, and holes are accumulated into the body B having a lower potential than those of the source S and the drain D. As a result, data “1” is written into all the memory cells MC01 and MC11 connected to the selected word line WL1 and the selected source line SL1. In this way, in the first cycle, data “1” is written into all the memory cells MC01 and MC11 connected to the selected word line WL1 and the selected source line SL1.

Potentials of the non-selected word lines WL0 and WL2 are a word line potential VWLL (−2.2 V, for example) at a data holding time. Potentials of the non-selected source lines SL0 and SL2 are the source line potential VSD1 (0 V) at a data holding time.

In the second cycle shown in FIG. 4B, data “0” is written into the memory cell MC01 connected to the selected word line WL1 and the selected bit line BL0. In this case, a potential of the selected word line WL1 as a fifth potential is a potential biased to the same polarity as the polarities of the majority carriers of the memory cells MC with reference to the source line potential as a sixth potential. A bit line potential as a fourth potential is a potential having an opposite polarity to the polarities of the majority carriers of the memory cells MC with reference to the source line potential as a sixth potential.

More specifically, VSD1 (0 V, for example) as the sixth potential is applied to all the source lines. The fourth potential VSDL (−0.9 V, for example) lower than the source line potential VSD1 is applied to the selected bit line BL0. The non-selected bit line BL1 is set to the potential VSD1 substantially equal to the source line potential VSD1. The fifth potential VWL0 (0.4 V, for example) higher than the selected source line potential VSD1 and the selected bit line potential VSDL is applied to the selected word line WL1. Based on a capacitance coupling of the word line and the body, the body potential becomes higher than the potentials of the source S and the drain D. As a result, a forward bias is applied to a pn junction between the body and the drain of the memory cell MC01. A forward current flows in the pn junction between the body and the drain, based on this forward bias. As a result, the holes accumulated in the body B are extracted (extinguished) to the drain D. On the other hand, because the potential of the bit line BL1 is the same ground potential as the source line potential VSD1, the memory cell MC11 maintains data “1”. As explained above, in the second cycle, data “0” is selectively written into the memory cell MC01 connected to the selected bit line BL0, out of the memory cells MC into which data “1” is written in the first cycle.

Potentials of the non-selected word lines WL0 and WL2 are the word line potential VWLL (−2.2 V, for example) at a data writing time, and a potential of the non-selected bit line BL1 is equal to the source line potential VSD1 (0 V) at a data holding time.

In the first embodiment, the sixth potential VSD1 is substantially equal to the first potential in the first cycle. The source line potential VSD1 as the sixth potential is set between potential levels of the fifth potential VWL0 and the fourth potential VSDL. That is, the fifth potential VWL0 and the fourth potential VSDL become potentials having mutually opposite polarities with reference to the source line potential VSD1. The second potential VWL1 and the fifth potential VWL0 are positive potentials of substantially the same polarity as those of the holes as majority carriers. Therefore, according to the first embodiment, in the first cycle, data “1” is written into the memory cells of all the columns connected to the selected word line. In the second cycle, data “0” is written into the selected memory cells connected to the selected word line and the selected bit line. Accordingly, desired logic data can be written into the memory cells MC connected to the selected word line.

Words “select” and “activate” mean to turn on or drive an element or a circuit, and “non-select” and “inactivate” mean to turn off or stop an element or a circuit. Therefore, a signal of HIGH (high potential level) can be a selected signal or an inactivated signal, and a signal of LOW (low potential level) can be a selected signal or an inactivated signal. For example, an NMOS transistor is selected (activated) by setting a gate to HIGH. On the other hand, a PMOS transistor is selected (activated) by setting a gate to LOW.

As described above, in a writing method according to the first embodiment, in the write operation of writing data “1”, the source line SL is selectively set to a high level potential, instead of setting the bit line potential to a high level. By setting a potential of the selected source line SL1 to the high level potential VSDH, holes necessary to write data “1” are generated by impact ionization. Because the source lines SL are extended in parallel with the word lines, holes are accumulated into all memory cells connected to the selected word line WL1. Because in the next second cycle, data “0” is written into the memory cell MC01 in which “0” is to be written, there is no problem when holes are accumulated in the first cycle. However, prior to the accumulation of holes in the first cycle, data “0” is sheltered into a sense amplifier. Therefore, the sense amplifier S/A is provided for each bit line.

In the second cycle, data “0” is written into the memory cell MC01. In this case, the memory cells MC01 and MC11 are different in potentials applied to the drains D. That is, a potential equal to the source line potential VSD1 is applied to the drain D of the memory cell MC11, and the fourth potential VSDL lower than the source line potential VSD1 is applied to the drain D of the memory cell MC01. Therefore, a difference between a threshold voltage of the “0” cell and that of the “1” cell depends on the fourth potential VSDL applied to the drain D.

According to a conventional write operation, the potential VSD1 of a selected bit line (a bit line for writing data “1”) needs to be set to a large value to take a large difference between the threshold voltage of the “0” cell and that of the “1” cell. However, taking a large value of the potential VSD1 of the selected line generates the above-described bit line “1” disturb to the non-selected memory cell connected to this selected bit line. On the other hand, when the potential VSD1 of the selected bit line is set to a large value, disturb of the bit line “1” is suppressed. However, a difference between the threshold voltage of the “0” cell and that of the “1” cell becomes small. As explained above, according to the conventional write operation, there is a tradeoff between a restriction of the bit line disturb and an increase of a difference between threshold voltages.

According to the first embodiment, regarding the memory cells MC connected to the non-selected word line, a drain voltage in the first cycle is substantially equal to a source voltage. Therefore, the bit line “1” disturb does not occur. On the other hand, when the potential VSDH of the selected source line in the first cycle is set to a high level, and also when the potential VSDL of the selected bit line in the second cycle is set to a low level, a difference between the threshold voltage of the “0” cell and that of the “1” cell can be set to a sufficiently large level. Therefore, according to the first embodiment, both the suppression of the bit line “1” disturb and the increase of the signal difference can be achieved.

When the potential VSDL of the selected bit line in the second cycle is set nearer to the source potential VSD1 than that of the conventional “0” writing to suppress the bit line “0” disturb, a difference between the threshold voltage of the “0” cell and that of the “1” cell can be maintained at a larger level than the conventional level, by sufficiently increasing the potential VSDH of the selected source line in the first cycle. Therefore, according to the first embodiment, not only the bit line “1” disturb can be restricted, but also the bit line “0” disturb can be restricted.

FIG. 4C shows a potential of each wiring in a data holding state. In the data holding state, all word lines WL are set to a potential of a polarity opposite to those of the majority carriers with reference to the source line potential and the bit line potential. For example, the source line potential and the bit line potential are set to the VSD1 (0 V), and all the word lines are set to the deeper negative potential VWLL (−2.2 V). Accordingly, a body potential of all the memory cells MC within the memory cell array becomes a deep negative potential. As a result, an accumulation state of the holes can be maintained.

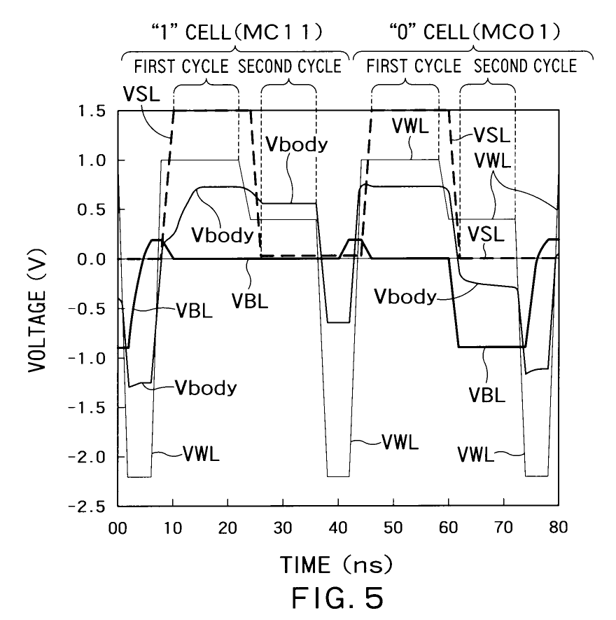

FIG. 5 is a timing diagram of voltages applied to the memory cells MC in the first cycle and the second cycle. A period of about 10 ns to 36 ns is a write operation period of data “1”. A period of about 46 ns to 72 ns is a write operation period of data “0”. FIG. 5 shows operations of the memory cells MC01 and MC11 in FIG. 4A and FIG. 4B sequentially in time. Because the memory cells MC0 and MC11 are connected to the same selected word line WL1, about 10 ns and about 46 ns can be actually regarded as the same time, and about 36 ns and about 72 ns can be actually regarded as the same time. That is, actual duration times of the first cycle and the second cycle are about 26 ns.

In this simulation, the SOI layer 30 has a film thickness 21 nm, the gate dielectric film GI has a film thickness 5.2 nm, a gate length is 75 nm, the BOX layer 20 has a film thickness 12.5 nm, and P-type impurity concentration of the body B is 1×10¹⁷cm⁻³. A fixed voltage of −2.4 V is applied to the plate (10).

During a period of about 10 ns to 12 ns, and during a period of about 46 ns to 48 ns, the source line driver SLD decreases the potential of the selected source line SL1 to the third potential VSDH, the word line driver WLD increases the potential of the selected word line WL1 to the second potential VWL1, and the sense amplifier S/A sets the bit line potential of the total columns to the first potential VSD1. During a period of about 12 ns to 22 ns, and during a period of about 48 ns to 58 ns, data “1” is written into the memory cells MC01 and MC11 (the first cycle).

During a period of about 22 ns to 24 ns, and during a period of about 58 ns to 60 ns, the word line driver WLD sets the potential of the selected word line WL1 to the fifth potential VWL0. A body potential Vbody drops based on a capacitance coupling between the body and the gate. Thereafter, the sense amplifier S/A decreases the potential of the bit line BL, which corresponds to the non-selected memory cell MC11 into which data “0” is not to be written, to the source line potential VSL. Accordingly, there is no potential difference between the drain and the source of the memory cell MC11. Therefore, data “0” is not written into the memory cell MC11. The sense amplifier S/A decreases the potential of the bit line BL, which corresponds to the selected memory cell MC01 into which data “0” is to be written, to the fourth potential VSDL lower than the source line potential VSL. Accordingly, a potential difference occurs between the drain and the source of the memory cell MC01. Consequently, holes within the body B are extinguished, and data “0” is written into the memory cell MC01. During a period of about 62 ns to 72 ns, data “0” is written into the memory cell MC01.

During a period of about 36 ns to 38 ns, and during a period of about 72 ns to 74 ns, the sense amplifier S/A returns the bit line potential to VSD1 (0 V). During a period of about 38 ns to 40 ns, and during a period of about 74 ns to 76 ns, the word line driver WLD decreases the potential of the word line WL1 to the potential VWLP (−2.2 V) in the data holding state. As a result, at about 40 ns and 76 ns, the memory cells MC01 and MC11 are in a data holding state (a pause state).

At about 7 ns, about 44 ns, and about 80 ns, the data read operation is performed. In this case, the word line potential is 1.0 V, and the bit line potential is 0.2 V. A drain current difference in this read operation is 67 μA/μm. The drain current difference depends on a difference (a signal difference) between a threshold voltage of the “1” cell and a threshold voltage of the “0” cell. Therefore, when the drain current difference is large, the sense amplifier S/A can detect data accurately and at a high speed.

To achieve a simple driving method, the word line voltage VWL1 in the first cycle can take the same value as that of the word line voltage VWL0 in the second cycle. When the word line voltage in the first cycle and the word line voltage in the second cycle are both 1.0 V, a drain current difference between the “0” cell and the “1” cell is 64 μA/μm. Because a word line voltage optimum to write data “1” is different from a word line voltage optimum to write data “0”, a signal amount decreases to some extent when the writing is performed at the same word line voltage. A body potential of the memory cell into which data “1” is written is higher than the voltage (0 V) of the source and the drain. Therefore, when a high word line voltage is held, holes are gradually extinguished near a forward biased PN junction. When the word line voltage in the second cycle is set higher to some extent than the word line voltage in the cycle, the body potential of the “1” cell decreases, and the writing into the “0” cell can be effectively performed while restricting the extinction of the holes in the “1” cell.

In the first embodiment, the refresh operation includes a sense amplifier refresh of once reading data from the memory cell MC, latching this data to the sense amplifier S/A, and writing back data of the same logic as that of this data to the same memory. The refresh operation further includes an autonomous refresh of simultaneously recovering both the “0” cell and the “1” cell using a body potential difference between the “0” cell and the “1” cell.

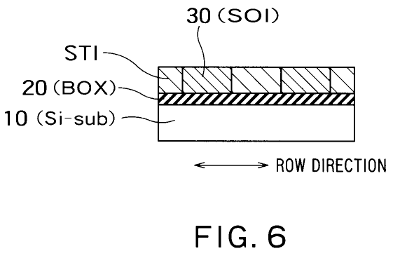

A method of manufacturing the FBC memory according to the first embodiment is explained with reference to FIG. 6 to FIG. 11. First, an SOI substrate is prepared. The BOX layer 20 has a film thickness 12.5 nm, and the SOI layer 30 has a film thickness 21 nm. A mask material (not shown) including a silicon nitride film is deposited on the SOI layer 30. A mask material and the SOI layer 30 in a shallow trench isolation are anisotropically etched. Next, an STI material including a silicon oxide film is filled into the shallow trench isolation. An SiN mask is removed by a hot phosphoric acid solution. As a result, a configuration shown in FIG. 6 is obtained. A p-type impurity of 1×10¹⁷cm⁻³ is introduced into the SOI layer 30. As a result, the body B is formed within the SOI layer 30.

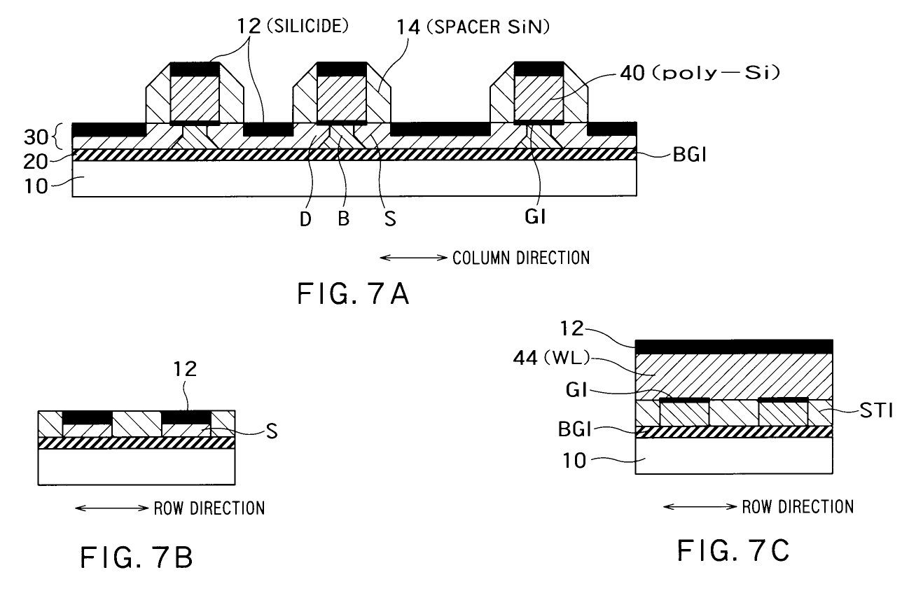

FIG. 7A, FIG. 7B, and FIG. 7C are cross-sectional views showing the manufacturing method following FIG. 6, and correspond to FIG. 3A, FIG. 3B, and FIG. 3C, respectively. An upper surface of the SOI layer 30 is heat oxidized to form the gate dielectric film GI on the SOI layer 30, as shown in FIG. 7A to FIG. 7C. An N-type polysilicon 50 is deposited next. The N-type polysilicon 40 is processed in a gate electrode pattern (a wiring pattern of the word line). A low concentration N-type impurity is introduced by ion implantation into a source formation region and a drain formation region by using the N-type polysilicon 40 as a mask. The spacer SiN 14 is formed on side surfaces of the word lines WL. A high concentration N-type impurity is introduced by ion implantation into the source formation region and the drain formation region. As a result, the source layer S and the drain layer D are formed within the SOI layer 30. The silicide 12 is formed on the surfaces of the word line WL, the source layer S, and the drain layer D.

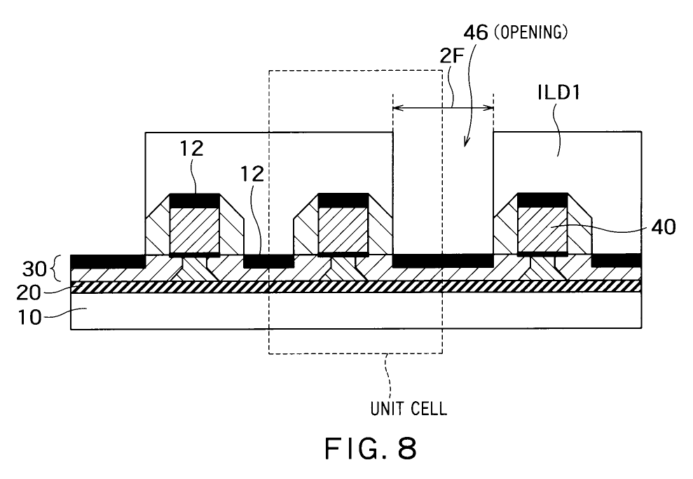

As shown in FIG. 8, an interlayer dielectric film (an oxide film, for example) ILD1 is deposited, and this is flattened by CMP (Chemical Mechanical Polishing). Next, to form the source line contact SLC, an opening 46 including two source line contacts SLC is formed in the interlayer dielectric film ILD1. In this case, the opening 46 has a width 2 F. In a unit cell according to a conventional technique, a source line contact of a diameter F has a width 0.5 F in a column direction. On the other hand, according to the first embodiment, the opening region has a width F in a column direction, in the unit cell. This F is a minimum size of a resist pattern that can be formed by a lithography technique in a certain generation.

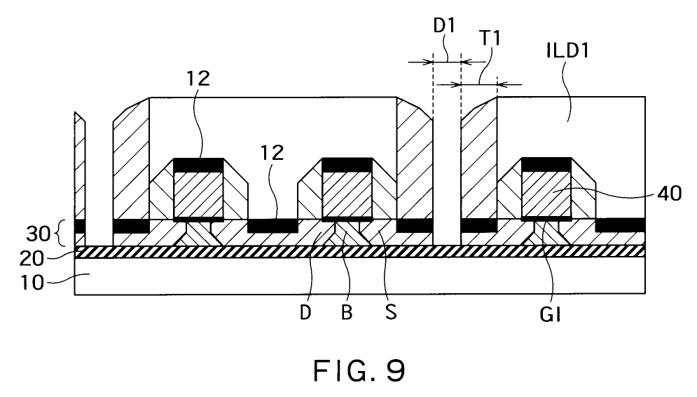

As shown in FIG. 9, tungsten having a film thickness Ti (T1<F) (0.75 F, for example) not blocking the opening 46 is deposited. Next, the tungsten is anisotropically etched so that tungsten at a bottom of the opening 46 is removed and tungsten on a sidewall of the opening 46 remains. The tungsten remaining on the sidewall of the opening 46 functions as the source line contact SLC. At the same time as the formation of the source line contact SLC, the source S and the silicide 12 are anisotropically etched. As a result, the source S and the silicide 12 are separated at a distance of D1 (D1=about 0.5 F) in a column direction.

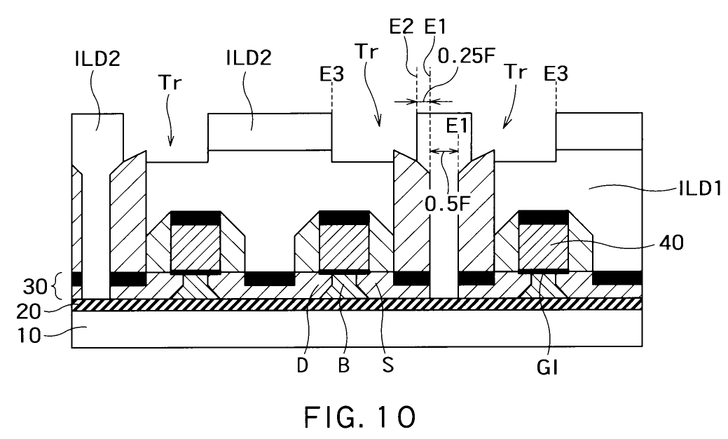

As shown in FIG. 10, an interlayer dielectric film (an oxide film, for example) ILD2 is deposited, and this is flattened by CMP. Next, to form the source line SL, a trench Tr is formed on the interlayer dielectric film ILD2. On a cross section along a column direction, ends E1 of adjacent source line contacts SLC are separated at a width 0.5 F. In the cross section along the column direction, a distance between the end E1 of the source line contact SLC and the end E2 of the trench Tr is 0.25 F. When an alignment error of a resist pattern between the trench Tr and the opening 46 of the source line contact SLC is equal to or smaller than 0.5 F, a low resistance source wiring can be formed, without short-circuiting adjacent source lines SL and without disconnecting the source line contact SLC and the source line SL. The other end E3 of the trench Tr is positioned above the word line WL. Therefore, the source line SL and the word line WL are formed to partially superimposed with each other. As a result, resistance of the source line SL becomes smaller.

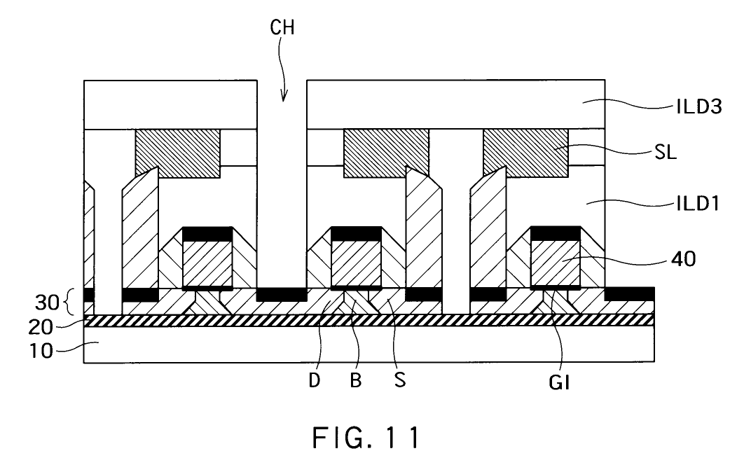

Next, as shown in FIG. 11, a metal material such as copper, aluminum, and tungsten is embedded into the trench Tr, thereby forming the source line SL. An interlayer dielectric film ILD3 is deposited, and a contact hole CH for the bit line contact BLC is formed. Thereafter, a metal material is embedded into the contact hole CH, thereby forming the bit line contact BLC. Further, a wiring of the bit line BL is formed. As a result, the FBC memory device shown in FIG. 3A to FIG. 3C is completed.

### Second Embodiment

A second embodiment of the present invention is different from the first embodiment in a data holding state (a state of memory cells holding data).

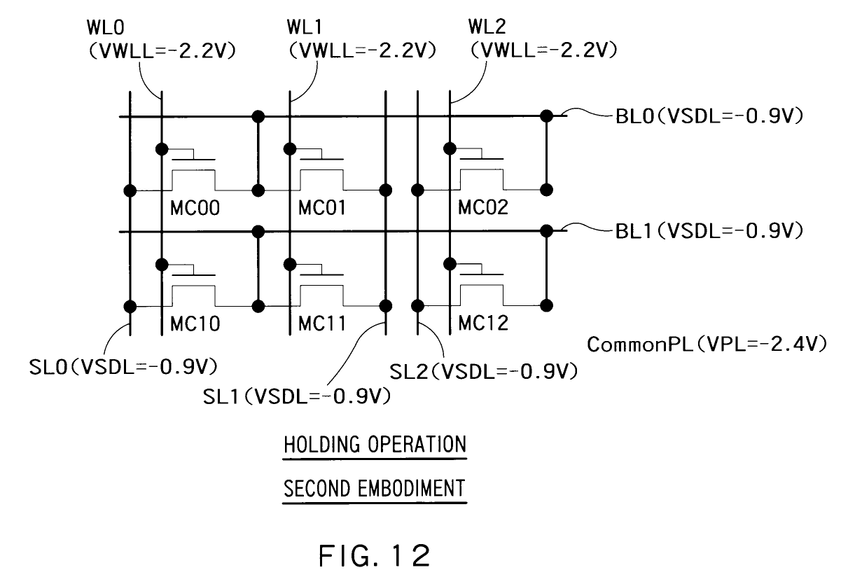

FIG. 12 shows a voltage state in a data holding according to the second embodiment. The voltage state in the data writing can be identical to those shown in FIG. 4A and FIG. 4B. A total bit line potential and a total source line potential at the data holding time are set as a seventh potential. A total word line potential at the data holding time is set as an eighth potential. The seventh potential with reference to the first or sixth potential VSD1 (0 V) has a polarity opposite to those of holes. Further, the word line potential VWLL (−2.2 V, for example) as the eighth potential has a polarity opposite to those of holes with reference to the bit line potential and the source line potential VSDL (−0.9 V) as the seventh potential. A plate potential VPL (−2.4 V, for example) as a ninth potential has a polarity opposite to those of holes with reference to the bit line potential as the seventh potential. In the second embodiment, the seventh potential VSDL (−0.9 V) is equal to the fourth potential in the first cycle. The eighth potential VWLL (−2.2 V, for example) is the same as a data holding potential of a word line in the first cycle. However, the seventh and eight potentials are not limited to these potentials.

In the second embodiment, the source line and bit line potentials VSDL (−0.9 V) at the data holding time are set lower than the reference potential VSD1 (0 V) at the data writing time. A data retention time of the “0” cell becomes long, when a source voltage at the data holding time decreases from 0 V to −0.9 V.

When a voltage difference VDG between the drain and the gate and a voltage difference VSG between the source and the gate at the data holding time are large, an electric field near the interface between the body and the gate electrode becomes large. When a voltage difference VDP between the drain and the plate and a voltage difference VSP between the source and the plate at the data holding time are large, an electric field near the interface between the body and the plate electrode becomes large. The increase in the electric field of the interface between the body and the gate and the increase in the electric field of the interface between the body and the plate cause a GIDL (Gate Induced Drain Leakage) current.

The GIDL current is a leak current generated by biasing the word line to a potential having a polarity opposite to those of the majority carriers of the memory cells MC with reference to the source line potential and the bit line potential. Further, the GIDL current is a leak current generated by biasing the plate to a potential having a polarity opposite to those of the majority carriers of the memory cells MC with reference to the source line potential and the bit line potential. The GIDL accumulates holes in the body of the “0” cell. Therefore, when data is held during a long period, data “0” is degraded.

On the other hand, when the source voltage and the drain voltage are set to −0.9 V at the data holding time like in the second embodiment, absolute values of VDG and VSG are 1.3 V, and absolute values of VDP and VSP are 1.5 V. Therefore, the electric field of the interface between the body and the gate and the electric field of the interface between the body and the plate become smaller than that of the first embodiment. As a result, the GIDL current becomes small, and a data retention time of the “0” becomes long.

In writing the data “1”, a difference between the plate voltage VPL (−2.4 V) and the source voltage or the drain voltage needs to be set to a large level to a certain extent. When the source voltage is −0.9 V, there is a possibility that the writing of the data “1” becomes insufficient. Therefore, at the writing time, preferably, the source potential is set to 0 V. Consequently, holes can be accumulated on a bottom surface of the body B facing the plate electrode (10). In the data read operation, a drain current difference between the data “0” and the data “1” can be also set to a large level, when the bottom of the body B is in the accumulated state. Therefore, at the data writing and reading times, a potential of the non-selected source line is set to VSD1 (0). Particularly, in the case of the FD-FBC, it is important that a deep negative potential with reference to the source voltage is applied to the plate at the data writing and reading times.

Further, when data is held by setting the word line potential to 0 V, the interface between the gate electrode and the body is depleted. When the interface is in the depleted state, a leak current via an interface state considerably increases. Therefore, preferably, data is held while keeping the interface in the accumulated state by setting the word line potential to a negative potential with reference to the source potential and the drain potential, in a similar manner to that of the plate potential.

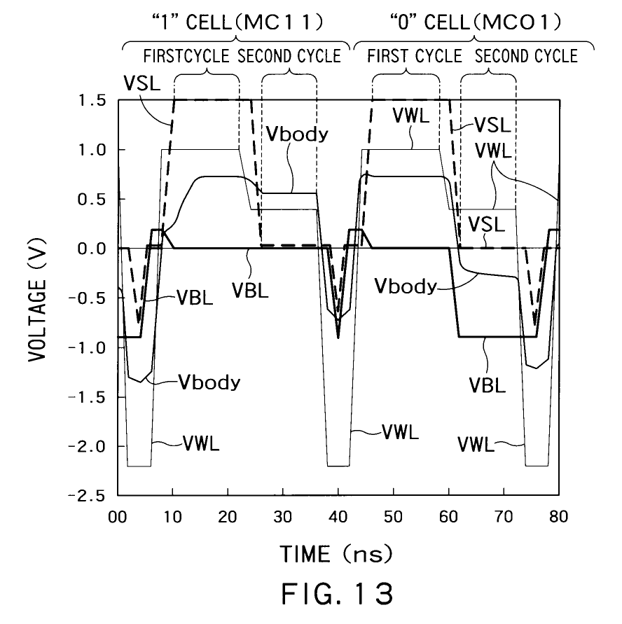

FIG. 13 is a timing diagram showing the operation of an FBC memory according to the second embodiment. First and second cycles in the second embodiment are identical to the first and second cycles in the first embodiment.

After performing the second cycle, during a period of about 36 ns to 38 ns and during a period of about 72 ns to 74 ns, the word line driver WLD decreases the potential of the word line WL1 to the word line potential VWLL (−2.2 V) at the data holding time. During a period of about 38 ns to 40 ns and during a period of about 74 ns to 76 ns, the sense amplifier S/A and the source line driver SLD decrease the bit line potential and the source line potential, respectively to the potential VSDL (−0.9 V) at the data holding time. In this case, the bit line potential and the source line potential as the seventh potential are substantially equal to the body potential of the “1” cell.

In the first embodiment, the bit line potential and the source line potential are VSD1 (0 V) at the data holding time. However, in the second embodiment, the bit line potential and the source line potential are decreased to the potential VSDL (−0.9 V). At about 76 ns, a maximum electric field of the “0” cell at the data holding time is 0.67 MV/cm. On the other hand, when the bit line potential and the source line potential are kept at VSD1 (0 V), a maximum electric field of the “0” cell is 0.97 MV/cm. As explained above, when the source line driver SLD changes the source potential to a potential having a polarity opposite to those of the holes at the time of shifting the write operation to the data holding, a maximum electric field of the “0” cells becomes small, and a data retention time becomes long.

### Third Embodiment

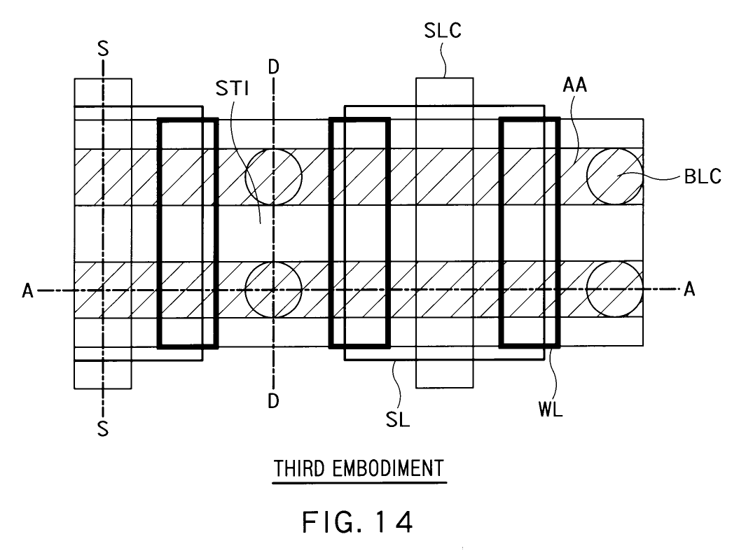

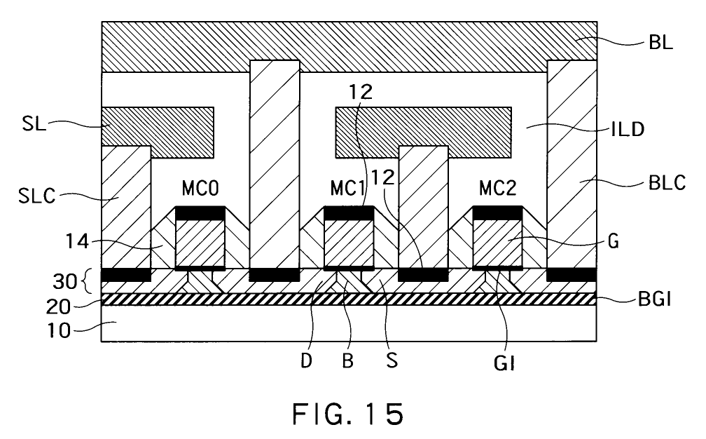

FIG. 14 and FIG. 15 are a plan view and a cross-sectional view, respectively of an FBC memory according to a third embodiment of the present invention. The third embodiment is different from the second embodiment in that two word line WL adjacent in a column direction are provided corresponding to one common source line SL. The memory cells MC connected to the two word lines of the first and second word lines are connected to one source line corresponding to the first and second word lines. Therefore, the FBC memory according to the third embodiment is superior in downscaling than the FBC memory according to the first and second embodiment.

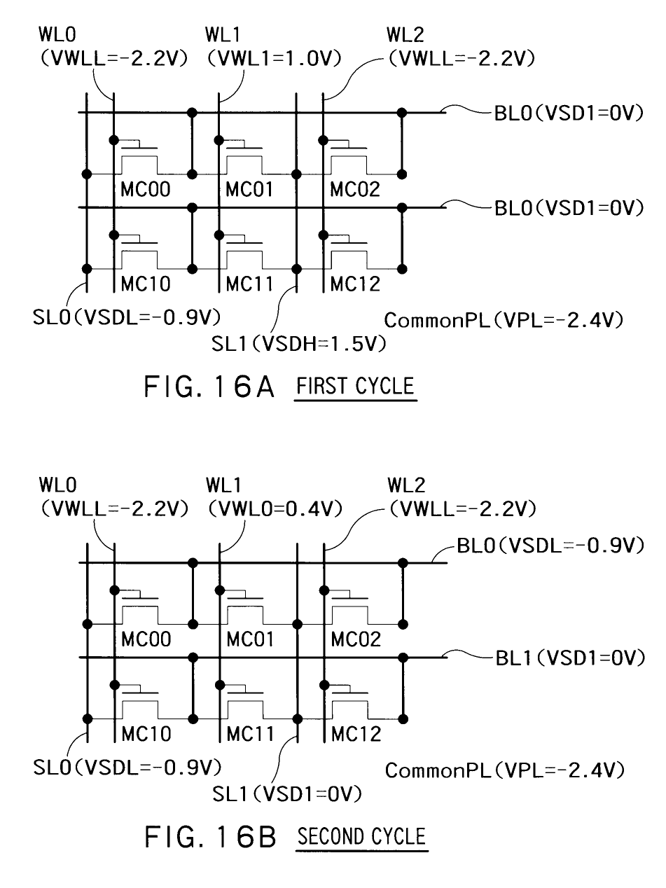

FIG. 16A and FIG. 16B are explanatory diagrams showing a data write operation. As shown in FIG. 16A, the selected source line SL1 corresponds to the selected first word line WL1 and the non-selected second word line WL2. The selected source line SL1 is connected to the memory cells MC02, MC12, MC01, and MC11.

A bit line voltage at the time of writing the data “1” is low. Therefore, disturb of the bit line “1” corresponding to the memory cells connected to the non-selected word line (excluding the non-selected word line sharing the selected word line and the source line) is suppressed.

A method of driving the memory cells MC in the first and second cycles is basically identical to that of the second embodiment. However, the operation of the memory cells connected to the non-selected second word line WL2 is different from that of the second embodiment. The operation of the memory cells connected to the non-selected second word line WL2 is explained below.

As shown in FIG. 16A, in the first cycle, the first potential VSD1 (0 V, for example) is applied to the drains of the memory cells MC02 and MC12, and the third potential VSDH (1.5 V, for example) is applied to the sources of the memory cells MC02 and MC12. The voltage VWLL (−2.2 V) is applied to the gates of the memory cells MC02 and MC12. As explained above, the memory cells connected to the non-selected second word line WL2 receive the disturb of the bit line “1” in a similar manner to that of a conventional technique. That is, the “0” cell connected to the non-selected second word line WL2 connected to the selected source line SL1 is degraded at a similar rate to that of the conventional technique.

The FBC memory according to the third embodiment can include a counter cell CC. The counter cell CC is provided for each of plural word lines WL, and a gate of each counter cell CC is connected to each word line WL. The counter cell CC can be the same as that of the memory cell MC to store data. The counter cell CC stores the number of times when each word line WL is activated to write data. Plural counter cells CC constitute a counter cell array arranged two-dimensionally.

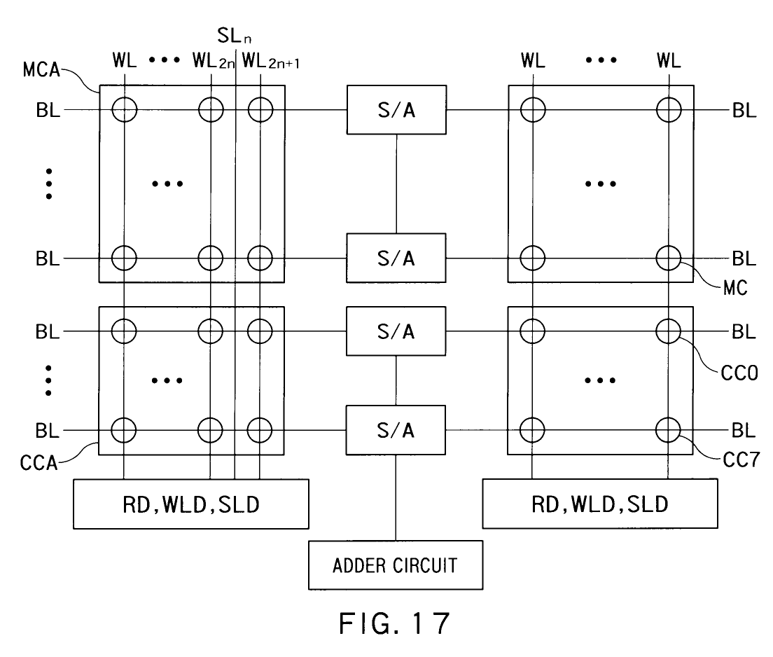

FIG. 17 is a configuration diagram showing one example of the FBC memory according to the third embodiment. A counter cell array CCA includes eight-bit counter cells CC provided corresponding to each word line WL. An adder circuit obtains total eight-bit data from counter cells CC0 to CC7 connected to a first word line WL2n each time the first word line WL2n is activated in a data read operation or data write operation. The adder circuit generates a digital value N by combining data from the counter cells CC0 to CC7, and adds (increments) one to this digital value to obtain a digital value N+1. Further, the adder circuit writes back the digital value N+1 to the counter cells C0 to C7. When the first word line WL2n is activated after the digital value N becomes a maximum value “11111111”, the adder circuit returns the digital value to zero. At the same time, the adder circuit performs a refresh of all memory cells MC connected to the second word line WL2n+1 sharing the first word line WL2n and the source line SLn. When the number of times of activating the word line WL2n+1 becomes a predetermined value, the adder circuit refreshes all memory cells MC connected to the word line WL2n.

As explained above, when the number of times of activating the first word line becomes a predetermined value, the adder circuit outputs an instruction to perform the refresh operation to the memory cells connected to the second word line. Accordingly, the memory cells MC connected to the second word line that is degraded in a similar manner to that according to the conventional technique can be properly refreshed.

When the number of times of activating the first word line has become a predetermined value, the adder circuit can output an instruction to perform the refresh operation to all memory cells MC connected to an adjacent third word line, as well as all memory cells MC connected to the second word line. In general, when the memory cells MC adjacent in a column direction share the drain D or the source S, holes in the body B of the “1” cell sometimes pass the drain D or the source S and flow to the adjacent “0” cell. That is, at the time of writing the data “1” by impact ionization, there is a conventional problem of bipolar disturb that the adjacent “0” cells are degraded via a diffusion layer giving a relatively low voltage out of the N-type source or the N-type drain of the memory cell into which the data is to be written. For example, assume, that in FIG. 15, the memory cell MC0 is the “0” cell, and that holes are generated by impact ionization near the source of the memory cell MC1 in the first cycle. A voltage 0 V is applied to the drain of the memory cell MC1, and 1.5 V is applied to the source of this memory cell MC1. It sometime happens that after sufficient holes are accumulated in the memory cell MC1, a part of overflowed holes passes the drain of the memory cell MC1, flows to the memory cell MC0, and degrades the “0” cells.

In the third embodiment, to solve the bipolar disturb, when the number of times of activating the first word line at the writing time becomes a predetermined value, all memory cells sharing the first word line and the drain or the source and connected to the second word line adjacent to the first word line are refreshed. Accordingly, the “0” cells degraded by the above-described disturb can be refreshed. The third embodiment can be widely applied to a memory having adjacent two word lines provided corresponding to one source line or one drain layer, and writing data “1” using impact ionization.

### Fourth Embodiment

The first to third embodiments can be applied to a fin transistor having a gate electrode provided on a side surface of the semiconductor layer 30 and having a channel formed on a side surface of the body B. The first to third embodiments can be also applied to a vertical transistor having a gate electrode provided on a side surface of the semiconductor layer 30 and passing source-drain currents to a perpendicular direction.

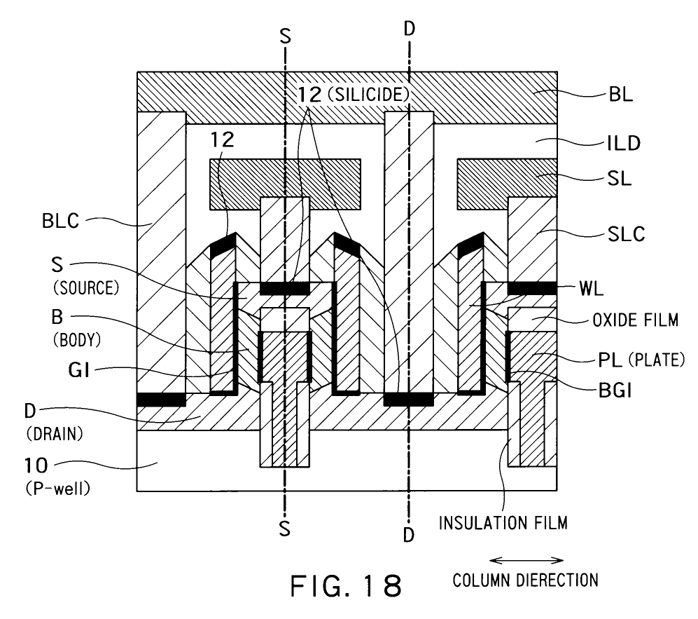

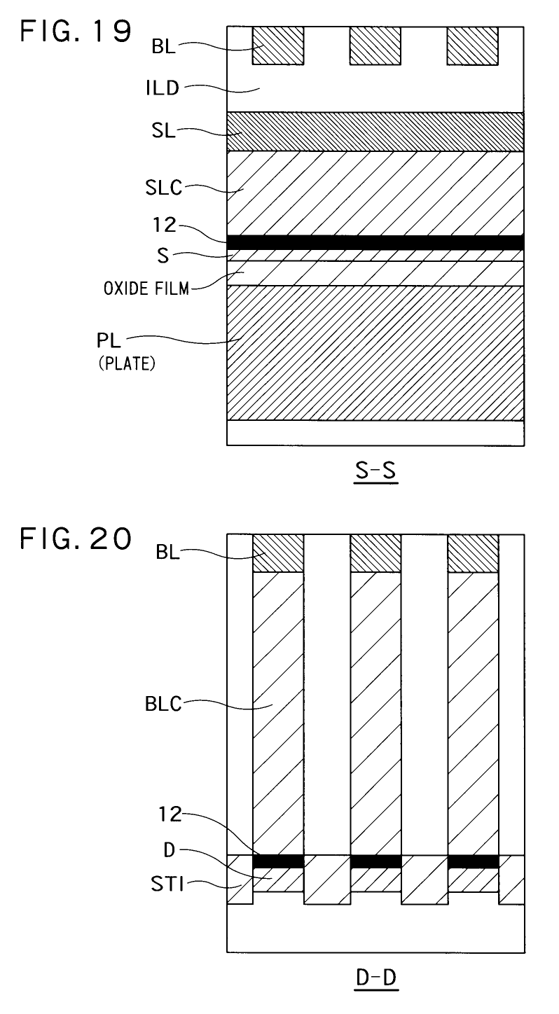

FIG. 18 to FIG. 20 are cross-sectional views showing one example of an FBC memory constituted by a vertical transistor according to a fourth embodiment of the present invention. The plan view is identical to FIG. 14. The vertical transistor includes the body B extended perpendicularly to the surface of the substrate 10. The drain D is formed in a semiconductor layer below the body B, and the source S is formed in an upper semiconductor layer. The source S of two memory cells adjacent in a column direction is common, and has a plane portion. The silicide 12 is formed on the plane portion of the source S. The source line contact SLC is formed on the silicide 12. Based on this configuration, parasitic resistance of the source S is small, and the source S can be selectively driven. The first to third embodiments can be also applied to this vertical transistor. To apply the first embodiment to the fourth embodiment, the source S needs to be separated for each word line WL, and the source line SL needs to be provided corresponding to each word line WL.

In the first to fourth embodiments, the memory cells MC are n-type FETs. However, the memory cells MC can be p-type FETs. In this case, the memory cells MC store data by accumulating electrons within the body B, or by discharging electrons. Therefore, a potential of each electrode (gate, source, and drain) and a potential of each wiring (word line, bit line, source line, and plate) in the first to fourth embodiments have a polarity opposite to the polarity described above. However, the size relationship of absolute values of the potentials of the electrodes and the potentials of the wirings can be identical as those explained in the first to fourth embodiments.

1. A semiconductor memory device comprising:
a plurality of memory cells each including a source, a drain, and a floating body in an electrically floating state, the memory cells storing logic data based on number of carriers within the floating body;
a plurality of bit lines connected to the drains;
a plurality of word lines crossing the bit lines, the word lines functioning as gates of the memory cells or being connected to gates of the memory cells;
a plurality of source lines connected to the sources, and extended along the word lines;
sense amplifiers detecting data stored in the memory cells; and
drivers driving the word lines or the source lines, wherein
in a first cycle of writing first logic data showing a state of a large number of the carriers to the memory cells, the sense amplifiers apply a first potential to the bit lines, the drivers respectively apply a second potential to a selected word line out of the word lines and a third potential to a selected source line out of the source lines, and the second and the third potentials with reference to the first potential have the same polarities as polarities of the carriers, and
in a second cycle of writing second logic data showing a state of a small number of the carriers to the memory cells, the sense amplifiers apply a fourth potential to a selected bit line out of the bit lines, the drivers respectively apply a fifth potential to the selected word line and a sixth potential to the selected source line and, the sixth potential is nearer to the first potential than the second and third potentials, the fifth potential with reference to the sixth potential has the same polarity as the polarities of the carriers, and the fourth potential with reference to the sixth potential has a polarity opposite to the polarities of the carriers.

2. A semiconductor memory device comprising:
a plurality of memory cells each including a source, a drain, and a floating body in an electrically floating state, the memory cells storing logic data based on number of carriers within the floating body;
a plurality of bit lines connected to the drains;
a plurality of word lines crossing the bit lines, the word lines functioning as gates of the memory cells or being connected to gates of the memory cells;
a plurality of source lines connected to the sources, and extended along the word lines;
sense amplifiers detecting data stored in the memory cells; and
drivers driving the word lines or the source lines, wherein
in the first cycle of driving the selected word line out of the word lines and the selected source line out of the source lines, the drivers write the first logic data showing the state of a large number of the carriers to the memory cells connected to the selected word line and the selected source line, and
in the second cycle of driving the selected bit line out of the plurality of bit lines, the sense amplifiers write the second logic data showing the state of a small number of the carriers selectively to the memory cells connected to the selected bit line out of the memory cells into which the first logic data is written in the first cycle.

3. The semiconductor memory device according to claim 2, wherein in the first cycle, the sense amplifiers apply the first potential to the bit lines, the drivers respectively apply the second potential to the selected word line out of the word lines and the third potential to the selected source line out of the source lines, and the second and the third potentials with reference to the first potential have the same polarities as the polarities of the carriers, and
in the second cycle, the sense amplifiers apply the fourth potential to the selected bit line out of the bit lines, the drivers respectively apply the fifth potential to the selected word line and the sixth potential to the selected source line, the sixth potential is nearer to the first potential than the second and the third potentials, the fifth potential with reference to the sixth potential has the same polarity as the polarities of the carriers, and the fourth potential with reference to the sixth potential has a polarity opposite to the polarities of the carriers.

4. The semiconductor memory device according to claim 1, wherein in the first cycle, the semiconductor memory device writes the first logic data to the memory cells by accumulating the carriers in the floating bodies using impact ionization, and in the second cycle, the semiconductor memory device writes the second logic data to the memory cells by extinguishing the carriers from the floating bodies using a forward current flowing in a junction between the floating bodies and the drains.

5. The semiconductor memory device according to claim 2, wherein in the first cycle, the semiconductor memory device writes the first logic data to the memory cells by accumulating the carriers in the floating bodies using impact ionization, and
in the second cycle, the semiconductor memory device writes the second logic data to the memory cells by extinguishing the carriers from the floating bodies using a forward current flowing in a junction between the floating bodies and the drains.

6. The semiconductor memory device according to claim 1, wherein in the second cycle, a potential of a non-selected bit line out of the bit lines is substantially equal to the sixth potential.

7. The semiconductor memory device according to claim 3, wherein in the second cycle, a potential of a non-selected bit line out of the bit lines is substantially equal to the sixth potential.

8. The semiconductor memory device according to claim 1, further comprising a source line contact provided in each of the plurality of memory cells.

9. The semiconductor memory device according to claim 2, further comprising a source line contact provided in each of the plurality of memory cells.

10. The semiconductor memory device according to claim 1, wherein in a data holding state, the sense amplifiers apply a seventh potential to the bit lines, the drivers apply the seventh potential to the source lines, and the seventh potential with reference to the first and the sixth potentials has a polarity opposite to the polarities of the carriers.

11. The semiconductor memory device according to claim 3, wherein in a data holding state, the sense amplifiers apply a seventh potential to the bit lines, the drivers apply the seventh potential to the source lines, and the seventh potential with reference to the first and the sixth potentials has a polarity opposite to the polarities of the carriers.

12. The semiconductor memory device according to claim 10, further comprising a plate facing each floating body via an insulation film on a surface of each floating body, wherein in the data holding state, the drivers apply an eighth potential to the word lines, apply a ninth potential to the plates in common with a data writing time, and the eighth potential and the ninth potential with reference to the seventh potential have polarities opposite to the polarities of the carriers.

13. The semiconductor memory device according to claim 11, further comprising a plate facing each floating body via an insulation film on a surface of each floating body, wherein
in the data holding state, the drivers apply an eighth potential to the word lines, apply a ninth potential to the plates in common with a data writing time, and the eighth potential and the ninth potential with reference to the seventh potential have polarities opposite to the polarities of the carriers.

14. The semiconductor memory device according to claim 10, wherein in the data holding state, the seventh potential is substantially equal to potentials of the floating bodies of the memory cells storing the first logic data.

15. The semiconductor memory device according to claim 11, wherein in the data holding state, the seventh potential is substantially equal to potentials of the floating bodies of the memory cells storing the first logic data.

16. The semiconductor memory device according to claim 1, further comprising:
a counter cell array including a plurality of counter cells provided corresponding to the word lines, the counter cell array storing number of activation of the word lines; and
an adder incrementing the number of activation of the selected word line, which number being readout from the counter cell array at each time of reading or writing data from or to the memory cells, wherein
adjacent a first and a second word lines out of the word lines are provided corresponding to one of the source lines, and
when the number of activation of the first word line becomes a predetermined value, the adder circuit outputs an instruction to perform a refresh operation of the memory cells connected to the second word line, the refresh operation recovering logic data stored in the memory cells.

17. The semiconductor memory device according to claim 2, further comprising:
a counter cell array including a plurality of counter cells provided corresponding to the word lines, the counter cell array storing number of activation of the word lines; and
an adder incrementing the number of activation of the selected word line, which number being readout from the counter cell array at each time of reading or writing data from or to the memory cells, wherein
adjacent a first and a second word lines out of the word lines are provided corresponding to one of the source lines, and
when the number of activation of the first word line becomes a predetermined value, the adder circuit outputs an instruction to perform a refresh operation of the memory cells connected to the second word line, the refresh operation recovering logic data stored in the memory cells.

18. A semiconductor memory device comprising:
a plurality of memory cells each including a source, a drain, and a floating body in an electrically floating state, the memory cells storing logic data based on number of carriers within the floating body;
a plurality of bit lines connected to the drains;
a plurality of word lines crossing the bit lines, the word lines functioning as gates of the memory cells or being connected to gates of the memory cells;
a plurality of source lines connected to the sources, and extended along the word lines;
sense amplifiers detecting data stored in the memory cells;
drivers driving the word lines or the source lines;
a counter cell array including a plurality of counter cells provided corresponding to the word lines, the counter cell array storing number of activation of the word lines; and
an adder circuit incrementing the number of activation of the selected word line, at each time of reading or writing data from or to the memory cells, wherein
adjacent a first and a second word lines out of the word lines are provided corresponding to one of the sources or one of the drains, and
when the number of activation of the first word line becomes a predetermined value, the adder circuit outputs an instruction to perform a refresh operation of the memory cells connected to the second word line, the refresh operation recovering logic data stored in the memory cells.
